(19) United States
(12) Patent Application Publication
(10) Pub. No.: US 2014/0235005 A1
(43) Pub. Date: Aug. 21, 2014

(54) METHOD OF PRODUCING P-TYPE NITRIDE SEMICONDUCTOR AND METHOD OF MANUFACTURING NITRIDE SEMICONDUCTOR LIGHT EMITTING DEVICE THEREWITH

(71) Applicant: SAMSUNG ELECTRONICS CO., LTD., Suwon-si (KR)

(72) Inventors: Jong Hyun LEE, Seoul (KR); Ki Sung KIM, Suwon-si (KR); Bum Joon KIM, Seoul (KR); Tan Sakong, Seoul (KR); Suk Ho YOON, Seoul (KR); Jae Deok JEONG, Ansan-si (KR)

(73) Assignee: SAMSUNG ELECTRONICS CO., LTD., Suwon-si (KR)

(21) Appl. No.: 14/106,783

(22) Filed: Dec. 15, 2013

(30) Foreign Application Priority Data
Feb. 15, 2013 (KR) 10-2013-0016313

(51) Int. Cl. H01L 33/00; H01L 21/02

(52) U.S. Cl. CPC H01L 33/0075; H01L 21/0254; H01L 21/02664
USPC 438/46; 438/493

(57) ABSTRACT

A method of producing a p-type nitride semiconductor includes growing a first nitride semiconductor layer doped with a first concentration of a p-type impurity. The first nitride semiconductor layer is annealed to activate the p-type impurity. A second nitride semiconductor layer doped with a second concentration of a p-type impurity is grown on the first nitride semiconductor layer. The second concentration is higher than the first concentration.

### CROSS-REFERENCE TO RELATED APPLICATION

This application claims benefit of priority from Korean Patent Application No. 10-2013-0016313, filed on Feb. 15, 2013 in the Korean Intellectual Property Office, the entire contents of which are hereby incorporated by reference.

### TECHNICAL FIELD

The present inventive concept relates to a method of producing a p-type nitride semiconductor, and more particularly, to a method of producing a p-type nitride semiconductor used in a nitride semiconductor light emitting device and a method of manufacturing a nitride semiconductor light emitting device with the p-type nitride semiconductor.

### BACKGROUND

In general, a nitride semiconductor light emitting device is known as a high-output optical device capable of implementing full color by generating blue, green or similar short-wavelength light. The nitride semiconductor light emitting device is manufactured using a group III—V-based compound semiconductor single crystal represented by a compositional formula of AlₓIn_{y}Ga_{(1-x-y)}N (0≦x≦1, 0≦y≦1, and 0≦x+y≦1).

In manufacturing a nitride semiconductor device, a p-type impurity of a p-type nitride semiconductor layer has a degree of electrical mobility lower than that of an n-type impurity of an n-type nitride semiconductor layer, such that a problem of an increased driving voltage may occur. In detail, since a p-type impurity of a p-type nitride semiconductor layer, such as Mg, has a property in which it is easily combined with hydrogen of ammonia as an ambient gas, electrical mobility may be deteriorated, resulting in an increased driving voltage level in the device. In order to address the problem as described above, an additional process of activating a p-type impurity is required.

### SUMMARY

An aspect of the present inventive concept relates to a method of producing a p-type nitride semiconductor capable of activating a p-type impurity while not deteriorating required characteristics and a method of manufacturing a nitride semiconductor light emitting device using the p-type nitride semiconductor.

One aspect of the present inventive concept encompasses a method of producing a p-type nitride semiconductor, including growing a first nitride semiconductor layer doped with a first concentration of a p-type impurity. The first nitride semiconductor layer is annealed to activate the p-type impurity. A second nitride semiconductor layer doped with a second concentration of a p-type impurity is grown on the first nitride semiconductor layer, the second concentration being higher than the first concentration.

The annealing of the first nitride semiconductor layer may be performed at a temperature of about 500° C. or higher.

The annealing of the first nitride semiconductor layer may be performed through physical contact. Unlike the description above, the annealing of the first nitride semiconductor layer may be performed through a contactless process of irradiating a laser beam onto a surface of the first nitride semiconductor layer.

The first and second nitride semiconductor layers may be formed of a material satisfying an empirical formula of AlₓIn_{y}Ga_{(1-x-y)}N (0≦x≦1, 0≦y≦1, 0≦x+y≦1).

The p-type impurity may be an element selected from magnesium (Mg), zinc (Zn), cadmium (Cd), beryllium (Be), calcium (Ca) and barium (Ba).

Another aspect of the present inventive concept relates to a method of manufacturing a nitride semiconductor light emitting device, including sequentially growing, on a substrate, an n-type nitride semiconductor layer and an active layer. A p-type nitride semiconductor layer doped with a first concentration of a p-type impurity is grown on the active layer. The p-type nitride semiconductor layer is annealed to activate the p-type impurity. A p-type nitride contact layer doped with a second concentration of a p-type impurity is grown on the p-type nitride semiconductor layer, the second concentration being higher than the first concentration.

The method may further include forming an electron blocking layer having a bandgap greater than a bandgap of the p-type nitride semiconductor layer, on the active layer, before the forming of the p-type nitride semiconductor layer.

The p-type nitride semiconductor layer may have a thickness of about 100 to about 500 nm and the p-type nitride contact layer may have a thickness of about 5 to about 40 nm.

Still another aspect of the present inventive concept encompasses a method of producing a p-type nitride semiconductor, including growing a first nitride semiconductor layer by supplying a source gas for a p-type impurity at a first flow amount. The first nitride semiconductor layer is annealed by stopping the growth of the first nitride semiconductor layer and stopping the supply of the source gas for the p-type impurity. A second nitride semiconductor layer is grown on the first nitride semiconductor layer by supplying the source gas for the p-type impurity at a second flow amount greater than the first flow amount.

The growing of the first nitride semiconductor layer may include supplying a source gas for the first nitride semiconductor layer.

The annealing of the first nitride semiconductor layer may include stopping the supply of the source gas for the first nitride semiconductor layer together with the source gas for the p-type impurity such that the growth of the first nitride semiconductor layer is converted into a nitrogen (N₂) atmosphere.

The annealing of the first nitride semiconductor layer may include supplying oxygen (O₂) or NH₂ gas.

The source gas for the p-type impurity may include Cp₂Mg, and the source gas for the first nitride semiconductor layer may include trimethylgallium (TMGa) and ammonia gas (NH₃).

### BRIEF DESCRIPTION OF THE DRAWINGS

The above and other aspects, features and other advantages of the present inventive concept will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a flowchart of a process illustrating a method of producing a p-type nitride semiconductor according to an embodiment of the present inventive concept.

FIG. 2 is chart illustrating a flow of supplied source gas used in a p-type nitride semiconductor manufacturing process according to an embodiment of the present inventive concept.

FIG. 3 is a graph illustrating driving voltage characteristics based on an annealing temperature of a p-type nitride semiconductor layer.

FIG. 4 is a schematic diagram of a vapor deposition device used in an embodiment of the present inventive concept by way of example.

FIGS. 5A to 5E are cross-sectional views of main processes for illustrating a method of manufacturing a nitride semiconductor light emitting device according to an embodiment of the present inventive concept.

FIG. 6 is a cross-sectional view of a nitride semiconductor light emitting device manufactured using the method of FIG. 5 by way of example.

### DETAILED DESCRIPTION

Embodiments of the present inventive concept will now be described in detail with reference to the accompanying drawings.

Embodiments of the present inventive concept may, however, be embodied in many different forms and should not be construed as being limited to embodiments set forth herein. Rather, these embodiments of the present inventive concept are provided so that this disclosure will be thorough and complete, and will fully convey the scope of the inventive concept to those skilled in the art.

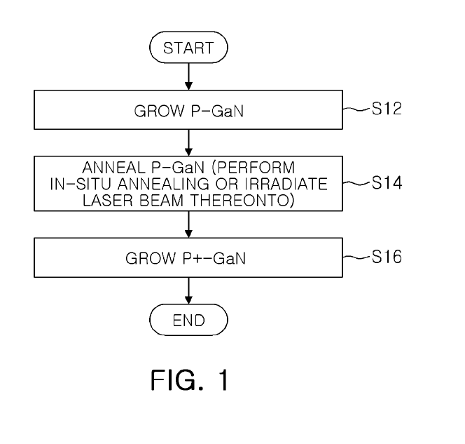

FIG. 1 is a flowchart of a process illustrating a method of producing a p-type nitride semiconductor according to an embodiment of the present inventive concept.

First, a first nitride semiconductor layer doped with a first concentration of a p-type impurity, as denoted by “P-GaN” in FIG. 1, may be grown in S12.

The first nitride semiconductor layer may be a layer of AlₓIn_{y}Ga_{(1-x-y)}N (0≦x≦1, 0≦y≦1, and 0≦x+y≦1), doped with a p-type impurity. The first p-type impurity concentration may be in the range of 5×10¹⁶˜1×10¹⁹/cm³. The p-type impurity may be an element selected from magnesium (Mg), zinc (Zn), cadmium (Cd), beryllium (Be), calcium (Ca) and barium (Ba). More specifically, Mg may be used as a p-type impurity.

A p-type impurity doped on the p-type nitride semiconductor layer, for example, magnesium (Mg) may be combined with hydrogen (H) derived from NH₃ to generate an Mg—H complex, and thus, a problem that the p-type impurity may not be activated may occur. In order to address such a problem, a process of activating a p-type impurity may be required.

Subsequently, the first nitride semiconductor layer may be (in-situ) annealed such that the p-type impurity is activated in S14.

The annealing process may be performed by stopping the process of forming the p-type nitride semiconductor layer. That is, the annealing process may be performed after the process of forming the p-type nitride semiconductor layer is completed and before a process of forming a second nitride semiconductor layer is performed.

In an activation process according to the present inventive concept, activation energy may be provided by the Mg—H complex through a high-temperature annealing process in which a hydrogen (H) atom is broken off such that Mg operates as a hole carrier. In such an annealing process, a hole carrier may be sufficiently activated in a p-type nitride semiconductor layer and a voltage level of a driving voltage may be decreased.

The annealing process as described above may be performed through physical contact. For example, a p-type nitride semiconductor layer may be annealed by heating a substrate through a susceptor within a process chamber. An annealing process according to the present inventive concept may be performed at a temperature of 500° C. or higher, and specifically, may be performed at a temperature lower than about 900° C.

Alternatively, an annealing process according to the present inventive concept may be implemented by contactless annealing. A representative contactless annealing scheme may be performed through a scheme in which activation energy is applied using a laser beam. An annealing process according to the present inventive concept may be performed through the process of irradiating a laser beam onto a surface of the p-type nitride semiconductor layer. In particular, the contactless annealing process using a laser beam may allow activation energy to be uniformly applied to the entire area of a substrate as compared to a contact annealing scheme using a heat treatment of a substrate. This will be described in more detail with reference to FIG. 4.

Next, in S16, a second nitride semiconductor layer doped with a second concentration of the p-type impurity, as denoted by “P+-GaN” in FIG. 1, may be grown on the first nitride semiconductor layer. The second impurity concentration may be higher than a first impurity concentration.

The second nitride semiconductor layer may include a region having a p-type impurity concentration higher than a p-type impurity concentration of the first nitride semiconductor layer, and may be generally provided as a contact layer on which a p-side electrode is formed in a semiconductor device structure. The second impurity concentration of the second nitride semiconductor layer may be about 1×10²⁰/cm³ or above.

In an annealing process for the activation of p-type impurity, damage to a crystal surface may occur during a process in which the activation energy is applied, and thus, an ohmic contact may not be formed at the time of forming contact with the p-side electrode. However, as in an embodiment according to the present inventive concept, p-type contact layer characteristics may be maintained by applying an annealing process thereto after the first nitride semiconductor layer occupying a main region of a p-type nitride semiconductor layer is formed and by then forming a high impurity concentration of second nitride semiconductor layer after the annealing process is completed.

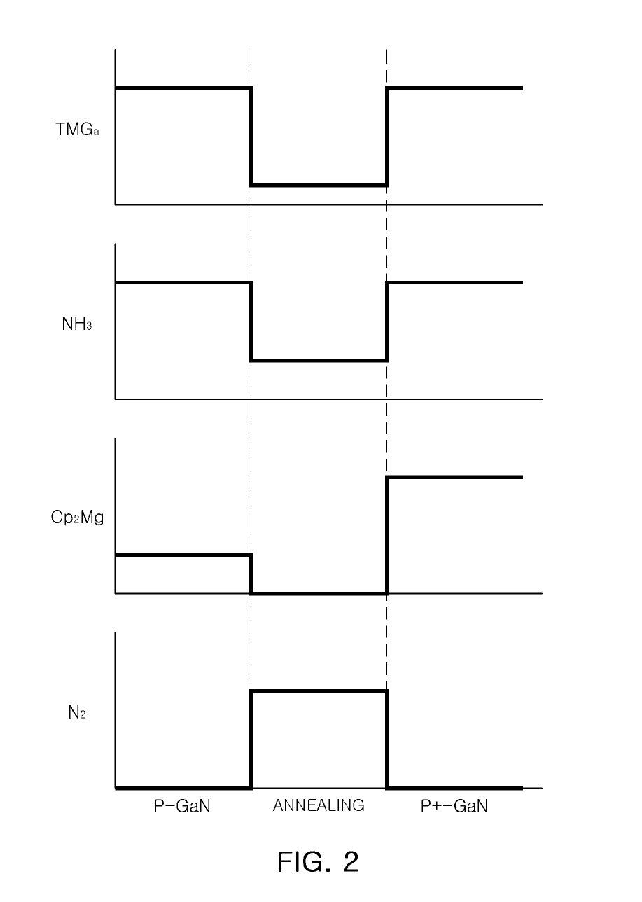

FIGS. 2A to 2D are charts illustrating a flow of source gas used in a p-type nitride semiconductor manufacturing process according to an embodiment of the present inventive concept.

The manufacturing process according to an embodiment of the present inventive concept will be described in more detail using a chart of FIG. 2 illustrating a flow of source gas per time period. The process illustrated in FIG. 2 may be understood as a growth process using metal organic chemical vapor deposition (MOCVD).

With reference to FIG. 2, as a source gas for the growth of a GaN semiconductor layer, trimethylgallium (TMGa) and ammonia gas (NH₃) may be provided, and as a p-type impurity, Cp₂Mg may be provided at a flow amount appropriate for implementing a desired impurity concentration. The source supplied as described above may be decomposed at a relatively high temperature to react on the substrate to thereby form a desired p-type nitride semiconductor layer.

Subsequently, the supply of trimethylgallium (TMGa) and ammonia gas (NH₃) together with the dopant source, Cp₂Mg, may be stopped such that the GaN growth may be stopped to then be converted into a nitrogen (N₂) atmosphere and perform an annealing process. H decomposed from Mg—H may react with nitrogen to then be removed through the annealing process performed in a nitrogen atmosphere. In addition to a nitrogen atmosphere, oxygen (O₂) may be mixed therewith at predetermined partial pressure as desired, and NH₂ gas may also be used additionally.

Referring to FIG. 2, after the annealing process is completed, trimethylgallium (TMGa) and ammonia gas (NH₃) may be supplied in order to re-grow a p-type GaN layer, and as a p-type impurity, Cp₂Mg may be provided at a flow amount appropriate for implementing a desired impurity concentration. The P-type GaN layer grown after the annealing process, i.e., “P+-GaN” as shown in FIG. 2, may be provided by significantly increasing a flow of Cp₂Mg so as to be provided as a p-type contact layer containing a high concentration of a p-type impurity, e.g., a concentration higher than a concentration in the “P-GaN”.

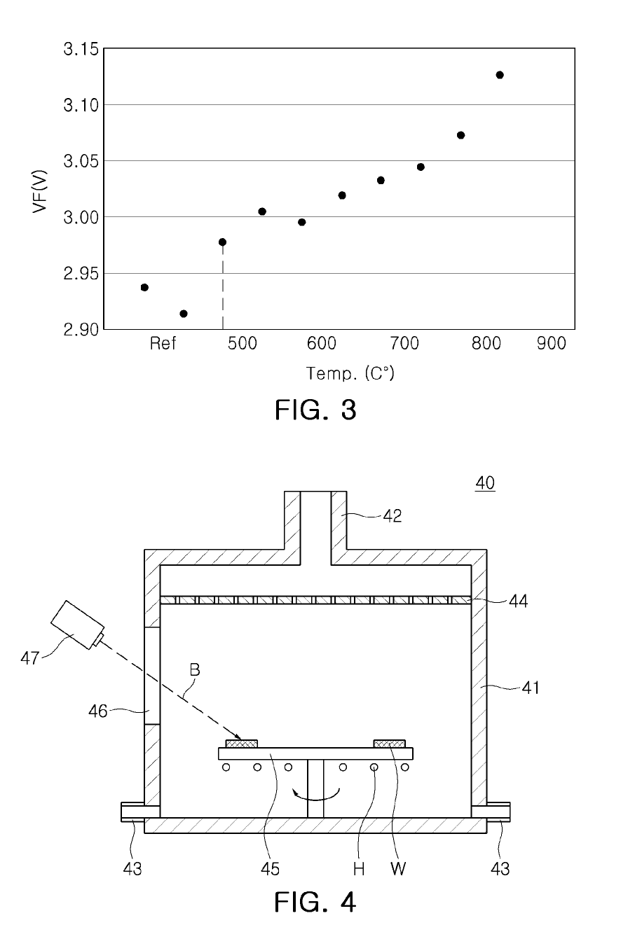

FIG. 3 is a graph illustrating driving voltage characteristics based on an annealing temperature of a p-type nitride semiconductor layer.

FIG. 3 provides a change in a driving voltage of a nitride semiconductor light emitting device according to an annealing temperature. As shown in FIG. 3, it can be appreciated that a driving voltage (VF) is increased through annealing at 500° C. or higher, and specifically, it can be seen that a driving voltage level (3.0V or more) is largely increased at a temperature higher than about 600° C. An annealing process according to the present inventive concept may be performed at about 900° C. or higher in order to prevent unnecessary impurity diffusion in an annealing process at an excessively high temperature.

FIG. 4 is a schematic diagram of a vapor deposition device used in an embodiment of the present inventive concept by way of example. The vapor deposition device shown in FIG. 4 is an example of a vapor deposition device designed to be appropriate for a contactless annealing process using a laser beam.

A vapor deposition device 40 shown in FIG. 4 may include a process chamber 41, a gas injection unit 42 disposed in an upper part thereof, a gas distributor 44 uniformly distributing an injected gas, and a gas discharging unit 43. The vapor deposition device 40 may have a vertical chamber structure in which a source gas is injected thereinto from above a substrate W. The vapor deposition device 40 may further include a susceptor 45 on which a substrate W is to be mounted, and a heater unit H heating the substrate W disposed on the susceptor 45. The vapor deposition device 40 may be considered to be a MOCVD process chamber. For example, when n-type GaN is formed, TMGa, NH₃ and SiH₄ may be provided as the source gas, and epitaxial growth may be carried out through chemical decomposition and reaction at a high growth temperature of about 900 to about 1300° C.

The process chamber 41 may include a window unit 46 provided with one side wall thereof. A laser device 47 may be provided such that a laser beam B therefrom may be irradiated onto a surface of the substrate W disposed on the susceptor 45 through the window unit 46.

In the vapor deposition device 40, the laser device 47 may irradiate the laser beam B onto a surface of p-type GaN layer before a high concentration p-type contact layer is formed, to thus activate a p-type impurity. In particular, after the p-type GaN layer is formed, stress may be generated due to a difference in thermal expansion coefficients between the p-type GaN layer and a substrate, for example, a sapphire substrate, formed of a material different from the material of the p-type GaN layer, thus generating a bending phenomenon in which the substrate is warped. When the substrate is warped to have a predetermined degree of curvature, a central portion of the substrate may contact a surface of the susceptor 45, while an edge region of the substrate W may not contact the susceptor 45 in a state in which the edge region is delaminated therefrom with a predetermined interval therebetween.

In this case, when the activation of the p-type impurity is attempted through the contact annealing process using the susceptor 45, a transfer of heat to the edge region of the substrate W may not appropriately be performed and thus, it may be difficult to secure p-type activation over the entire region of the p-type GaN layer.

However, in the vapor deposition device 40 according to an embodiment of the present inventive concept, a uniform heat treatment may be secured over the entire region of the substrate W, even in the phenomenon in which the substrate W is warped by scanning in the scheme of directly irradiating the laser beam B on the substrate (W) surface through the window 46.

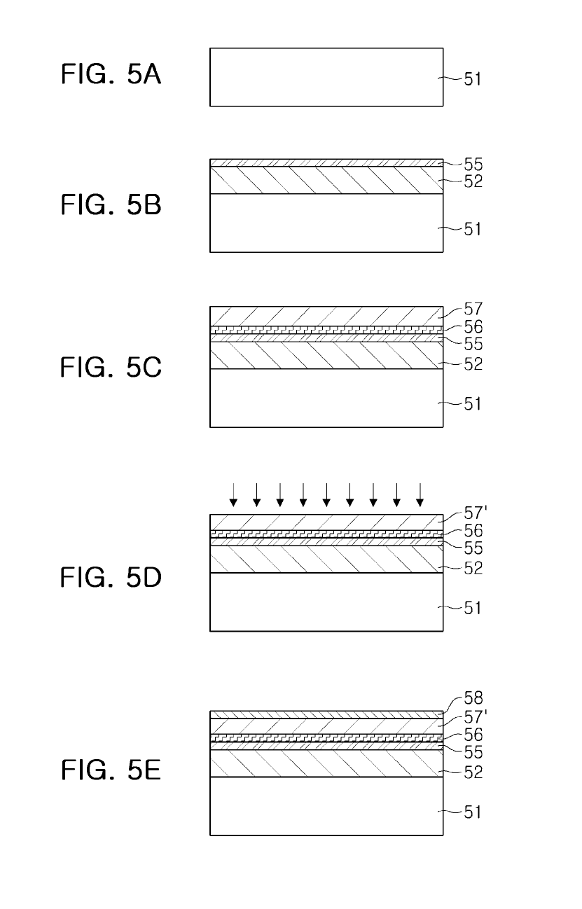

FIGS. 5A to 5E are cross-sectional views of main processes for illustrating a method of manufacturing a nitride semiconductor light emitting device according to an embodiment of the present inventive concept.

With reference to FIG. 5A, the present method may initially be performed by preparing a substrate 51. The substrate 51 for the growth of a nitride semiconductor crystal may be a substrate formed of sapphire, SiC, Si, MgAl₂O₄, MgO, LiAlO₂, LiGaO₂, or GaN. The substrate 51 may be a GaN substrate, for example, a substrate for epitaxial growth of a GaN material. Warping may be generated at the time of a change in temperature due to a difference in thermal expansion coefficients between a substrate material and a nitride single crystal material, and the warping may become a factor generating cracks in a film layer. In order to decrease the problem as described above, a buffer layer (not separately shown) may be formed between the substrate 51 and alight emitting laminate, for example, a semiconductor single crystal.

There may be a case in which the substrate 51 is completely or partially removed or patterned during a chip manufacturing process before or after growth of a light emitting diode (LED) structure in order to improve optical or electrical characteristics of an LED chip. For example, in the case of a sapphire substrate, the substrate may be separated by irradiating a laser beam onto an interface between the substrate and the nitride semiconductor layer through the substrate. In the case of a silicon or silicon carbide substrate, the substrate may be removed through a method such as polishing/etching or the like.

When the substrate is patterned, concave-convex portions or an inclined surface may be formed on one or both of main surfaces of the substrate, or side surfaces of the substrate, before or after the growth of an LED structure to thus improve light extraction efficiency. The size of a pattern may be selected from within a range of about 5 nm to about 500 μm and any pattern structure capable of increasing light extraction efficiency using a regular or irregular pattern can be used. The pattern may be variously formed, for example, may have a pillar form, a peak-valley form, a semispherical form, or the like.

In the case of using a sapphire substrate to grow a nitride single crystal, sapphire may be a crystal having Hexa-Rhombo R3c symmetry, and may have respective lattice constants of 13.001 Å and 4.758 Å in c-axis and a-axis directions, and may have a C (0001) plane, an A (1120) plane, an R (1102) plane and the like. In this case, since the C plane comparatively facilitates the growth of a nitride thin film and is stable at relatively high temperatures, the C plane may be mainly used as a growth substrate for a nitride semiconductor.

Meanwhile, as another substrate suitable for use as the substrate 51, a Si substrate may be used. The Si substrate is appropriate for obtaining a substrate having a large diameter, and implementing slimness and lightness while having relatively low manufacturing costs, thereby facilitating mass production thereof. The Si substrate having, as a substrate surface, a (111) plane, has a difference of about 17% between the Si substrate and the GaN substrate in terms of lattice constants thereof. Thus, a technology of suppressing the occurrence of a crystal defect due to a difference in lattice constants may be required. In addition, a difference in thermal expansion rates between silicon and GaN is about 56%, and a technology of suppressing warping of a wafer due to differences in rates of thermal expansion may be required. When the wafer is warped, since a GaN thin film may have cracks therein and it may be difficult to control a process, a problem may occur such that the distribution of light emitting wavelengths may be increased within a single wafer.

In the viewpoint of a warping phenomenon in a wafer, an annealing method using a laser beam may be appropriate therefor in that when the annealing is performed using a contactless scheme, e.g., the annealing method using a laser beam, a warping phenomenon may be reduced as compared with a contact scheme in which heat is transferred through the substrate.

Subsequently, as shown in FIG. 5B, a first conductive nitride semiconductor layer 52 and an active layer 55 may be sequentially formed on the substrate 51.

The first conductive nitride semiconductor layer 52 may be a nitride single crystal doped with an n-type impurity and having a composition of AlₓIn_{y}Ga_{1-x-y}N (0≦x≦1, 0≦y≦1, 0≦x+y≦1). The active layer 55 may have a multiple quantum well (MQW) structure in which quantum well layers and quantum barrier layers are alternately stacked on top of each other, and for example, may have a GaN/InGaN structure in the case of a nitride semiconductor. Here, a single quantum well (SQW) structure may also be used.

Although the first conductive nitride semiconductor layer 52 may be implemented to have a single layer structure, the first conductive nitride semiconductor layer 52 may have a multilayer structure having different compositions or thicknesses, or the like, as needed. For example, the first conductive semiconductor layer 52 may be provided with an electro injection layer capable of improving electron injection efficiency, and may also include various super-lattice structures.

The first conductive semiconductor layer 52 may further include a current diffusion layer (not separately shown) on a portion thereof adjacent to the active layer 55. The current diffusion layer may have a structure in which a plurality of InₓAl_{y}Ga_{(1-x-y)}N layers (here, 0≦x≦1, 0≦y≦1, and 0≦x+y≦1) having different compositions or different impurity contents are repeatedly stacked or an insulating layer is partially formed.

Subsequently, as shown in FIG. 5C, an electron blocking layer 56 and a p-type nitride semiconductor layer 57 may be formed on the active layer 55.

The electron blocking layer 56 may be a layer to prevent electrons having relatively high mobility from being overlapped with a p-type region and may be formed of a nitride semiconductor layer having an energy bandgap greater than an energy bandgap of the p-type nitride semiconductor layer 57. The electron blocking layer 56 may be provided as a nitride semiconductor layer having a relatively high content of Al such as in AlGaN.

The p-type nitride semiconductor layer 57 may representatively be a p-type GaN layer. The p-type nitride semiconductor layer 57 may have a p-type impurity concentration ranging about 5×10¹⁶/cm³ to about 5×10¹⁹/cm³. The p-type nitride semiconductor layer 57 may have a thickness of about 100 nm to about 500 nm.

Next, an annealing process may be undertaken such that the p-type nitride semiconductor layer 57 is activated.

In an activation process according to the present inventive concept, a hydrogen (H) atom may be broken off in the Mg—H complex through a high-temperature annealing process such that an Mg hole operates as a carrier to thus provide an activated p-type nitride semiconductor layer 57′. The annealing process as described above may be performed through a physical contact scheme or a contactless scheme.

In the contact scheme, the p-type nitride semiconductor layer may be subjected to an annealing process by heating a substrate through a susceptor in the process chamber. An annealing process according to the present inventive concept may be performed at a temperature of 500° C. or higher, and specifically, may be performed at a temperature lower than about 900° C.

In a contactless annealing scheme according to the present inventive concept, a scheme of applying activation energy using a laser beam may be provided. That is, the contactless annealing scheme may be performed through a process of irradiating a laser beam onto a surface of the p-type nitride semiconductor layer. In particular, the contactless annealing process using a laser beam may uniformly apply activation energy to the entire area of the substrate as compared with a contact annealing scheme through a heat treatment of a substrate.

Then, as shown in FIG. 5E, a p-type contact layer 58 may be formed on the activated p-type nitride semiconductor layer 57′.

The p-type contact layer 58 may include a region providing an ohmic contact with the p-side electrode and may be mainly provided as a GaN layer doped with a high concentration p-type impurity. The impurity concentration of the p-type contact layer 58 may be about 1×10²⁰/cm³ or higher. The p-type contact layer 58 may have a thickness ranging from about 5 nm to about 40 nm. The p-type contact layer 58 may not be subjected to a separate annealing process such that a surface thereof does not have damage thereon. Even when the p-type contact layer is not activated, since the activated p-type nitride semiconductor layer 57′ is provided as a main p-type region, an effective hole-carrier concentration may be provided.

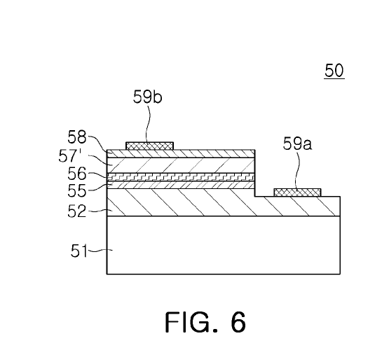

FIG. 6 illustrates an example of a nitride semiconductor light emitting device 50 manufactured through the process of FIG. 5.

The n-type nitride semiconductor layer 52 and the p-type contact layer 58 may be provided with an n-side electrode 59a and a p-side electrode 59b, respectively. The p-type contact layer 58 may decrease a device operating voltage and improve device characteristics by relatively increasing an impurity concentration to reduce ohmic contact resistance. The n-side electrode 59a and the p-side electrode 59b may include Ag, Ni, Al, Rh, Pd, Ir, Ru, Mg, Zn, Pt, Au, or the like, and may have a two-layer or more structure such as Ni/Ag, Zn/Ag, Ni/Al, Zn/Al, Pd/Ag, Pd/Al, Ir/Ag. Ir/Au, Pt/Ag, Pt/Al, Ni/Ag/Pt, or the like.

In the nitride semiconductor light emitting device 50 manufactured in a process according to the present inventive concept, since a separate annealing process is not applied to the p-type contact layer 58, the surface thereof may not have damage thereto and therefore a good quality ohmic contact with the p-side electrode 59b may be achieved. Meanwhile, the p-type nitride semiconductor layer 57′, a main region of the p-type region, may be activated before the p-type contact layer 58 is formed, whereby a relatively high effective hole-carrier concentration may be secured to provide a driving voltage reduction effect.

As set forth above, according to embodiments of the present inventive concept, a p-type nitride semiconductor layer having improved electrical characteristics without damage to a crystal layer providing a contact region during an activation process may be manufactured by annealing a p-type nitride semiconductor layer before forming a crystal layer for contact with an electrode so as to activate a p-type impurity.

While the present inventive concept has been shown and described in connection with embodiments, it will be apparent to those skilled in the art that modifications and variations can be made without departing from the spirit and scope of the present inventive concept as defined by the appended claims.

What is claimed is:

1. A method of producing a p-type nitride semiconductor, comprising:
growing a first nitride semiconductor layer doped with a first concentration of a p-type impurity;
annealing the first nitride semiconductor layer to activate the p-type impurity; and
growing a second nitride semiconductor layer doped with a second concentration of a p-type impurity on the first nitride semiconductor layer, the second concentration being higher than the first concentration.

2. The method of claim 1, wherein the annealing of the first nitride semiconductor layer is performed at a temperature of about 500° C. or higher.

3. The method of claim 1, wherein the annealing of the first nitride semiconductor layer is performed through physical contact.

4. The method of claim 1, wherein the annealing of the first nitride semiconductor layer includes irradiating a laser beam onto a surface of the first nitride semiconductor layer.

5. The method of claim 1, wherein the first and second nitride semiconductor layers are formed of a material satisfying an empirical formula of AlₓIn_{y}Ga_{(1-x-y)}N (0≦x≦1, 0≦y=1, 0≦x+y≦1).

6. The method of claim 1, wherein the p-type impurity is an element selected from the group consisting of magnesium (Mg), zinc (Zn), cadmium (Cd), beryllium (Be), calcium (Ca) and barium (Ba).

7. A method of manufacturing a nitride semiconductor light emitting device, comprising:
sequentially growing, on a substrate, an n-type nitride semiconductor layer and an active layer;
growing a p-type nitride semiconductor layer doped with a first concentration of a p-type impurity on the active layer;
annealing the p-type nitride semiconductor layer to activate the p-type impurity; and
growing a p-type nitride contact layer doped with a second concentration of a p-type impurity on the p-type nitride semiconductor layer, the second concentration being higher than the first concentration.

8. The method of claim 7, wherein the annealing of the p-type nitride semiconductor layer is performed at a temperature of about 500° C. or higher.

9. The method of claim 7, wherein the annealing of the p-type nitride semiconductor layer is performed through physical contact.

10. The method of claim 7, wherein the annealing of the p-type nitride semiconductor layer includes irradiating a laser beam onto a surface of the p-type nitride semiconductor layer.

11. The method of claim 7, wherein the p-type nitride semiconductor layer and the p-type nitride contact layer are respectively formed of a material satisfying an empirical formula of AlₓIn_{y}Ga_{(1-x-y)}N (0≦x≦1, 0≦y≦1, 0≦x+y≦1).

12. The method of claim 11, wherein the p-type nitride semiconductor layer and the p-type nitride contact layer are respectively a GaN layer.

13. The method of claim 7, wherein the p-type impurity is an element selected from the group consisting of magnesium (Mg), zinc (Zn), cadmium (Cd), beryllium (Be), calcium (Ca) and barium (Ba).

14. The method of claim 7, further comprising forming an electron blocking layer having a bandgap greater than a bandgap of the p-type nitride semiconductor layer, on the active layer, before the forming of the p-type nitride semiconductor layer.

15. The method of claim 7, wherein the p-type nitride semiconductor layer has a thickness of about 100 nm to about 500 nm and the p-type nitride contact layer has a thickness of about 5 nm to about 40 nm.

16. A method of producing a p-type nitride semiconductor, comprising:
growing a first nitride semiconductor layer by supplying a source gas for a p-type impurity at a first flow amount;
annealing the first nitride semiconductor layer by stopping the growth of the first nitride semiconductor layer and stopping the supply of the source gas for the p-type impurity; and
growing a second nitride semiconductor layer on the first nitride semiconductor layer by supplying the source gas for the p-type impurity at a second flow amount greater than the first flow amount.

17. The method of claim 16, wherein the growing of the first nitride semiconductor layer includes supplying a source gas for the first nitride semiconductor layer.

18. The method of claim 17, wherein the annealing of the first nitride semiconductor layer includes stopping the supply of the source gas for the first nitride semiconductor layer together with the source gas for the p-type impurity and converting an atmosphere for the growth of the first semiconductor layer into a nitrogen (N₂) atmosphere.

19. The method of claim 18, wherein the annealing of the first nitride semiconductor layer includes supplying oxygen (O₂) or NH₂ gas.

20. The method of claim 17, wherein:
the source gas for the p-type impurity includes Cp₂Mg, and
the source gas for the first nitride semiconductor layer includes trimethylgallium (TMGa) and ammonia gas (NH₃).
